(19) United States
(12) Patent Application Publication
(10) Pub. No.: US 2022/0199669 A1
(43) Pub. Date: Jun. 23, 2022

(54) IMAGE SENSING DEVICE

(71) Applicant: SK hynix Inc., Icheon-si (KR)

(72) Inventor: Eun Khwang LEE, Icheon-si (KR)

(21) Appl. No.: 17/338,219

(22) Filed: Jun. 3, 2021

(30) Foreign Application Priority Data
Dec. 22, 2020 (KR) 10-2020-0180917

(51) Int. Cl. H01L 27/146

(52) U.S. Cl. CPC H01L 27/14625; H01L 27/14621

(57) ABSTRACT

An image sensing device is provided to include a substrate including a first surface and a second surface, a color filter formed over the first surface, a photoelectric conversion element formed in the substrate and arranged to correspond to the color filter, and one or more polarizers formed between the first surface and the photoelectric conversion element and embedded in the substrate. The one or more polarizers are configured to transmit light of polarization oriented in a specific direction and block light of polarization oriented in other directions than the specific direction.

### CROSS-REFERENCE TO RELATED APPLICATION

This patent document claims the priority and benefits of Korean patent application No. 10-2020-0180917, filed on Dec. 22, 2020, which is incorporated by reference in its entirety as part of the disclosure of this patent document.

### TECHNICAL FIELD

The technology and implementations disclosed in this patent document generally relate to an image sensing device, and more particularly to technology for an image sensing device capable of improving polarization performance BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IOT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device including one or more polarizers embedded in a substrate. In some implementations, the polarizers are arranged to have different widths or heights based on colors of color filters, thereby improving polarization performance and preventing crosstalk.

In accordance with an embodiment of the disclosed technology, an image sensing device may include a substrate including a first surface and a second surface opposite to the first surface, a color filter disposed over the first surface and configured to transmit light at a certain wavelength to the substrate, a photoelectric conversion element disposed in the substrate and configured to produce an electric signal in response to the light incident to the photoelectric conversion element, and one or more polarizers disposed between the first surface and the photoelectric conversion element and embedded in the substrate, and wherein the one or more polarizers are configured to transmit light of polarization oriented in a specific direction and block light of polarization oriented in other directions than the specific direction.

In accordance with another embodiment of the disclosed technology, an image sensing device may include a pixel array including imaging pixels that are arranged in rows and columns, and wherein each imaging pixel includes: a substrate; a photoelectric conversion element disposed in the substrate and configured to produce an electrical signal in response to light incident to the photoelectric conversion element; a color filter disposed over the substrate and configured to transmit light at a certain wavelength to the photoelectric conversion element; and a polarizer disposed in the substrate and configured to transmit light of polarization oriented in a specific direction and block light of polarization oriented in other directions than the specific direction, and wherein polarizers of the imaging pixels have different sizes depending on wavelengths of light transmitted by color filters.

In accordance with another embodiment of the disclosed technology, an image sensing device may include a substrate, imaging pixels supported by the substrate and structured to convert light into electrical signals, a first color filter formed over a first surface and configured to transmit light of a first color towards a first imaging pixel of the imaging pixels, a second color filter formed over the first surface and configured to transmit light of a second color towards a second imaging pixel of the imaging pixels, a first polarizer formed below the first color filter and embedded in the substrate to polarize light of the first color that is directed to the first imaging pixel, and a second polarizer formed below the second color filter and embedded in the substrate to polarize light of the second color that is directed to the second imaging pixel.

### BRIEF DESCRIPTION OF THE DRAWINGS

FIG. 1 is a block diagram illustrating an example of an image sensing device based on an embodiment of the disclosed technology.

FIG. 2 is a cross-sectional view illustrating an example of a unit pixel of a pixel array shown in FIG. 1 based on an embodiment of the disclosed technology.

FIG. 3 is a perspective view illustrating an example of the shape of a substrate shown in FIG. 2 based on an embodiment of the disclosed technology.

FIGS. 4 to 8 are cross-sectional views illustrating examples of shapes of a polarizer shown in FIG. 2 based on embodiments of the disclosed technology.

FIG. 9 is a perspective view illustrating an example of an embedded structure of polarizers shown in FIG. 4 based on an embodiment of the disclosed technology.

FIGS. 10 and 11 are cross-sectional views illustrating examples of shapes of polarizers shown in FIG. 4 based on embodiments of the disclosed technology.

### DETAILED DESCRIPTION

This patent document provides implementations and examples of an image sensing device for improving polarization performance Some implementations of the disclosed technology suggest an image sensing device which can effectively prevent crosstalk while simultaneously minimizing loss of light.

Hereafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

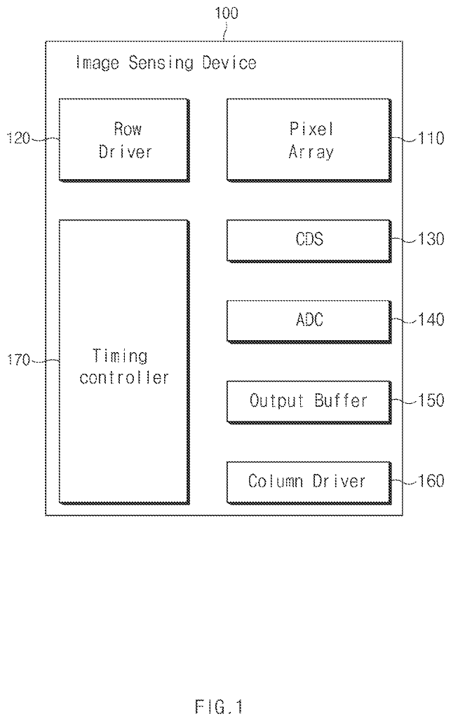

FIG. 1 is a block diagram illustrating an image sensing device according to an embodiment of the disclosed technology.

Referring to FIG. 1, the image sensing device 100 may include a pixel array 110, a row driver 120, a correlated double sampler (CDS) 130, an analog-digital converter (ADC) 140, an output buffer 150, a column driver 160 and a timing controller 170. The components of the image sensing device 100 illustrated in FIG. 1 are discussed by way of example only, and this patent document encompasses numerous other changes, substitutions, variations, alterations, and modifications.

The pixel array 110 may include a plurality of unit imaging pixels arranged in rows and columns. In one example, the plurality of unit imaging pixels can be arranged in a two dimensional pixel array including rows and columns. In another example, the plurality of unit imaging pixels can be arranged in a three dimensional pixel array. The plurality of unit pixels may convert an optical signal into an electrical signal on a unit pixel basis or a pixel group basis, where unit pixels in a pixel group share at least certain internal circuitry. The pixel array 110 may receive driving signals, including a row selection signal, a pixel reset signal and a transmission signal, from the row driver 120. Upon receiving the driving signal, corresponding imaging pixels in the pixel array 110 may be activated to perform the operations corresponding to the row selection signal, the pixel reset signal, and the transmission signal.

The row driver 120 may activate the pixel array 110 to perform certain operations on the imaging pixels in the corresponding row based on commands and control signals provided by controller circuitry such as the timing controller 170. In some implementations, the row driver 120 may select one or more imaging pixels arranged in one or more rows of the pixel array 110. The row driver 120 may generate a row selection signal to select one or more rows among the plurality of rows. The row driver 120 may sequentially enable the pixel reset signal for resetting imaging pixels corresponding to at least one selected row, and the transmission signal for the imaging pixels corresponding to the at least one selected row. Thus, a reference signal and an image signal, which are analog signals generated by each of the imaging pixels of the selected row, may be sequentially transferred to the CDS 130. The reference signal may be an electrical signal that is provided to the CDS 130 when a sensing node of an imaging pixel (e.g., floating diffusion node) is reset, and the image signal may be an electrical signal that is provided to the CDS 130 when photocharges generated by the imaging pixel are accumulated in the sensing node.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

In some implementations, the CDS 130 may transfer the reference signal and the image signal of each of the columns as a correlate double sampling signal to the ADC 140 based on control signals from the timing controller 170.

The ADC 140 is used to convert analog CDS signals into digital signals. In some implementations, the ADC 140 may be implemented as a ramp-compare type ADC. The ramp-compare type ADC may include a comparator circuit for comparing the analog pixel signal with a reference signal such as a ramp signal that ramps up or down, and a timer counts until a voltage of the ramp signal matches the analog pixel signal. In some embodiments of the disclosed technology, the ADC 140 may convert the correlate double sampling signal generated by the CDS 130 for each of the columns into a digital signal, and output the digital signal. The ADC 140 may perform a counting operation and a computing operation based on the correlate double sampling signal for each of the columns and a ramp signal provided from the timing controller 170. In this way, the ADC 140 may eliminate or reduce noises such as reset noise arising from the imaging pixels when generating digital image data.

The ADC 140 may include a plurality of column counters. Each column of the pixel array 110 is coupled to a column counter, and image data can be generated by converting the correlate double sampling signals received from each column into digital signals using the column counter. In another embodiment of the disclosed technology, the ADC 140 may include a global counter to convert the correlate double sampling signals corresponding to the columns into digital signals using a global code provided from the global counter.

The output buffer 150 may temporarily hold the column-based image data provided from the ADC 140 to output the image data. In one example, “the image data provided to the output buffer 150 from the ADC 140 may be temporarily stored in the output buffer 150 based on control signals of the timing controller 170. The output buffer 150 may provide an interface to compensate for data rate differences or transmission rate differences between the image sensing device 100 and other devices.

The column driver 160 may select a column of the output buffer upon receiving a control signal from the timing controller 170, and sequentially output the image data, which are temporarily stored in the selected column of the output buffer 150. In some implementations, upon receiving an address signal from the timing controller 170, the column driver 160 may generate a column selection signal based on the address signal and select a column of the output buffer 150, outputting the image data as an output signal from the selected column of the output buffer 150.

The timing controller 170 may control operations of the row driver 120, the ADC 140, the output buffer 150 and the column driver 160.

The timing controller 170 may provide the row driver 120, the column driver 160 and the output buffer 150 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

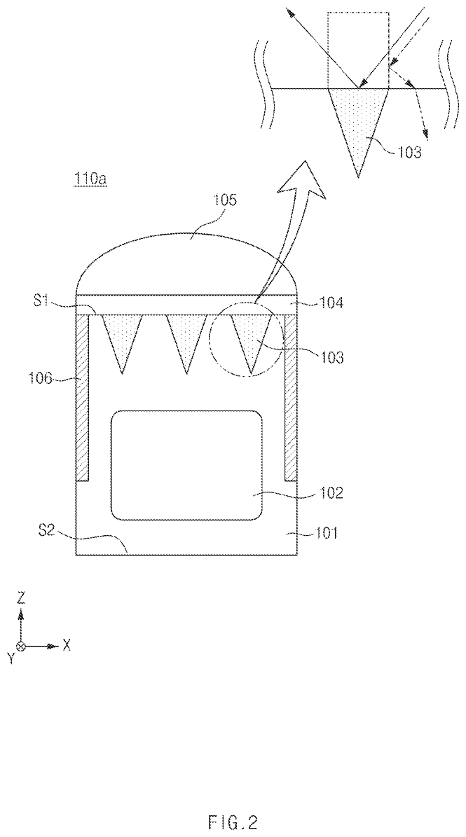

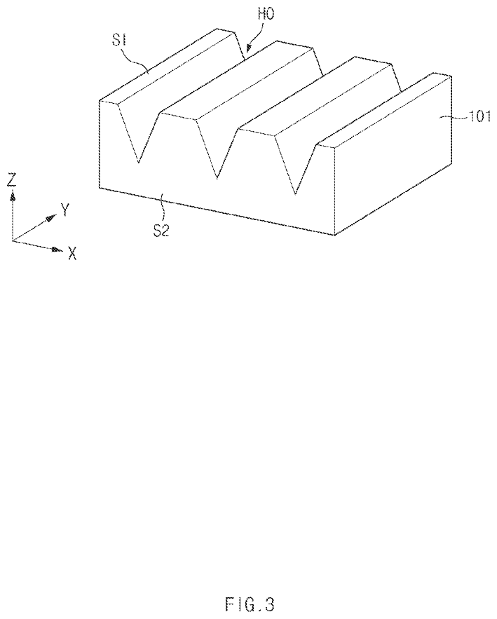

FIG. 2 is a cross-sectional view illustrating an example of a unit pixel 110a of the pixel array 110 shown in FIG. 2 based on an embodiment of the disclosed technology. Although the pixel array 110 shown in FIG. 1 includes a large number of unit pixels, only one unit pixel 110a is shown in FIG. 2 for convenience of description. FIG. 3 is a perspective view illustrating an example of the shape of a substrate shown in FIG. 2.

Referring to FIG. 2, the unit pixel 110a may include a substrate 101, a photoelectric conversion element 102, at least one polarizer 103, a color filter 104, a lens layer 105, and a device isolation layer 106.

For convenience of description, two directions that are arranged to cross each other while being parallel to a top surface of the substrate 101 will hereinafter be defined as a first direction (X-axis direction) and a second direction (Y-axis direction), and another direction vertically protruding from the top surface of the substrate 101 will hereinafter be defined as a third direction (Z-axis direction). The first direction (X-axis direction) and the second direction (Y-axis direction) may be substantially perpendicular to each other. The third direction (Z-axis direction) may correspond to one direction perpendicular to each of the first direction and the second direction.

The substrate 101 may include a first surface S1 and a second surface S2 that are opposite to each other. The second surface S2 of the substrate 101 may be referred to as a front side, and the first surface S1 of the substrate 101 may be referred to as a back side. It is also possible that the second surface S2 and the first surface S1 of the substrate are arranged to be the back side and the front side, respectively. The substrate 101 may be in a monocrystalline state, and may include a silicon-containing material. The substrate 101 may include P-type impurities. For example, the substrate 101 may be a P-type or N-type bulk substrate. For example, the substrate 101 may be formed by growing a P-type or N-type epitaxial layer on the P-type bulk substrate. For example, the substrate 101 may be a substrate formed by growing a P-type or N-type epitaxial layer on the N-type bulk substrate. The photoelectric conversion element 102 and one or more polarizers 103 may be formed in the substrate 101. The color filter 104 and the lens layer 105 may be sequentially stacked over the substrate 101 in the third direction.

Unit pixels, each configured to convert incident light into photocharges to generate electrical signals corresponding to the photocharges, may be formed in the substrate 101. Each unit pixel may include a photoelectric conversion element 102 and a plurality of transistors (not shown). For example, assuming that each unit pixel of the CMOS image sensor includes a 5-transistor (5T) structure, the unit pixel may include a reset transistor for resetting a floating diffusion (FD) node (not shown), a source follower transistor for amplifying photocharges and transmitting the amplified photocharges, a selection transistor for outputting a pixel signal to a column line coupled to the unit pixel, a transfer transistor for transmitting the photocharges to the floating diffusion (FD) node (not shown), and a bias transistor. However, a detailed description of a plurality of transistors (not shown) will herein be omitted from the following description of the unit pixel shown in FIG. 2.

The photoelectric conversion element 102 shown in FIG. 2 may be disposed in a region of a corresponding unit pixel 110a in the substrate 101. The photoelectric conversion element 102 may generate and accumulate photocharges corresponding to intensity of light (e.g., visible light) having a specific wavelength band. Light may be incident upon the photoelectric conversion element 102 after passing through the lens layer 105, the color filter 104, and the polarizers 103. The photoelectric conversion element 102 may generate photocharges through photoelectric conversion of incident light received through the first surface S1. For example, the photoelectric conversion element 102 may generate a pair of an electron and a hole in response to incident light.

For example, the photoelectric conversion element 102 may be implemented as an organic or inorganic photodiode, a phototransistor, a photogate, or a pinned photoelectric conversion element or a combination thereof. If the photoelectric conversion element 102 is implemented as a photodiode, the photoelectric conversion element 102 may be formed as an N-type doped region through ion implantation of N-type ions. In one embodiment, the photodiode may be formed by stacking a plurality of doped regions. In this case, a lower doped region may be formed by implantation of N⁺ ions, and an upper doped region may be formed by implantation of N⁻ ions. The photoelectric conversion element 102 may be arranged across as large a region as possible to increase a fill factor indicating light reception (Rx) efficiency. In one embodiment, a device isolation layer 106 disposed between photoelectric conversion elements of the contiguous or adjacent pixels may be formed to be deeply etched in a vertical direction, so that the device isolation layer 106 can electrically or optically isolate the contiguous or adjacent pixels that are located adjacent to each other.

The polarizers 103 may selectively transmit light of polarization oriented in a specific direction among the incident light having penetrated the lens layer 105. Therefore, among incident light applied to the image sensing device 100, the polarizers 103 may transmit light of polarization in the specific direction only (e.g., same polarization direction as the light emitted from the target object), and may block the light of polarization oriented in other directions (e.g., noise).

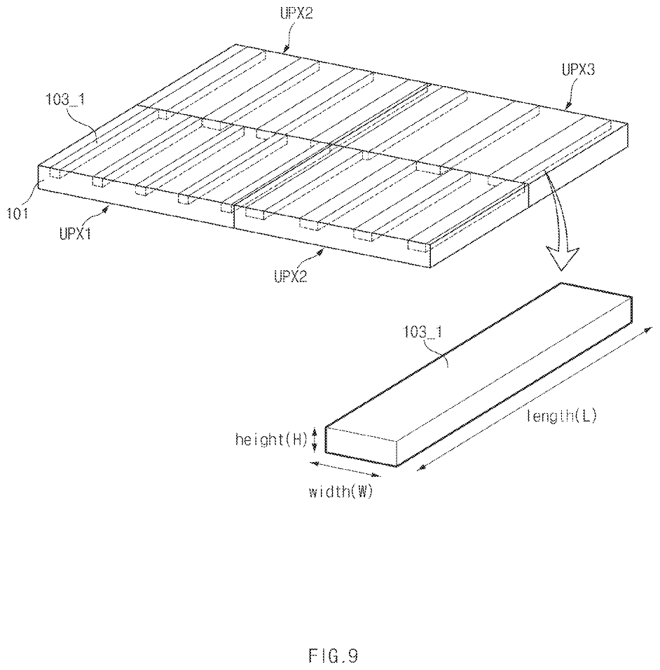

In some implementations, the polarizer(s) 103 may be implemented as wire grid polarizer(s) as will be described later with reference to FIG. 9. The polarizers 103 may be consecutively arranged in the first direction (X-axis direction) at intervals of a predetermined distance. The polarizers 103 may be formed at a lower portion (i.e., first surface S1) of the color filter 104. The polarizers 103 may be formed between the color filter 104 and the photoelectric conversion element 102.

The polarizers 103 may be embedded in the substrate 101. Each of the polarizers 103 may have a triangular cross-section in which the width of a horizontal direction (i.e., first direction or X-axis direction) of the polarizer 103 gradually decreases in a direction from the first surface S1 to the second surface S2. If each polarizer 103 is formed in an inverted triangular shape, the width of a polarization direction (i.e., an electrical-field direction) along which light will be transmitted gradually decreases so that the amount of light capable of penetrating the polarizer 103 can increase. In one embodiment, if the polarizer 103 is implemented as an inverted triangular polarizer, the amount of metal materials to be used in the inverted triangular polarizer may be relatively small compared to a rectangular-shaped polarizer, resulting in reduction in production costs. The polarizer 103 may be formed of metal. In one embodiment, the polarizer 103 may also be formed by stacking the same metal materials or different metal materials.

As illustrated in FIG. 3, the substrate 101 from which the polarizers 103 are removed may have an engraved shape in which V-shaped grooves (HO) are formed in the first surface S1. For example, after the substrate 101 is etched in a manner that uneven portions, each of which has a triangular cross-section, are formed in the first surface S1 of the substrate 101, materials (e.g., metal) of the polarizer 103 may be deposited. Although FIG. 2 and FIG. 3 illustrate that only three polarizers 103 are formed in the substrate 101, the number of such polarizers 103 embedded in the substrate 101 is not limited thereto and can be varied.

Each polarizer 103 may be a linear polarization element which transmits light of polarization in the specific direction, and reflects light of polarization oriented other directions. Thus, the light of polarization oriented in other directions than the specific direction of the polarization is removed. When the polarizers 103 are formed on a top surface of the substrate 101 and have side surfaces exposed over the substrate 101 (as represented with a dotted rectangular as shown in the right corner of FIG. 2), light obliquely incident upon the polarizers 103 may be reflected from side surfaces of the polarizers 103 and the reflected light can be incident upon the substrate 101. Such light that is reflected and then enters into the substrate 101 can cause crosstalk, which results in the reduction on the light polarization performance. Thus, when the polarizers 103 are formed on the top surface of the substrate 101 and have exposed side surfaces, a range of an acceptance angle that allows the polarizer to perform the desired polarization performance may be small.

The polarizers 103 based on the embodiment of the disclosed technology may be embedded in the substrate 101, so that the side surfaces of the polarizers 103 are not exposed outside. Since the polarizers 103 are formed in the substrate 101, there is a reduced portion that is exposed over the substrate 101, which makes light incident upon the polarizers 103 at an oblique angle can be less absorbed in the substrate 101. Accordingly, the image sensing device based on the embodiments of the disclosed technology can prevent light incident upon the substrate 101 at various angles from being reflected and re-incident upon the substrate 101, thereby improving polarization performance.

The color filter 104 may be disposed over the substrate 101 and the polarizers 103 in a manner that upper portions of the substrate 101 and the polarizers 103 are covered with the color filter 104. The color filter 104 may be formed to selectively transmit color light corresponding to each pixel. The color filter 104 may perform filtering of specific visible light having a specific wavelength band from among wavelength bands of visible light incident through the lens layer 105, and may thus selectively transmit the filtered light. For example, the color filter 104 may include a red filter configured to transmit only red light from among RGB (Red, Green, Blue) lights of visible light, a green filter configured to transmit only green light from among RGB lights of visible light, and a blue filter configured to transmit only blue light from among RGB lights of visible light. The red (R) filter, the green (G) filter, and the blue (B) filter contained in the color filter 104 may be arranged in a Bayer pattern. In addition, the color filter 104 may further include at least one of a cyan filter, a yellow filter, a magenta filter, a white filter, or a black filter. In one embodiment, if the unit pixel corresponds to a depth pixel, the color filter 104 may be omitted or may be replaced with an infrared (IR) pass filter.

The lens layer 105 may direct (or guide) incident light to be efficiently incident upon the photoelectric conversion element 102 of the unit pixels. The lens layer 105 may converge the incident light received from outside, and may transmit the converged light to the color filter 104. The lens layer 105 disposed over the color filter 104 may be formed in a hemispherical shape. The lens layer 105 may include a microlens (or on-chip lenses) formed over the color filter 104. In one embodiment, the lens layer 105 may include a digital lens. An over-coating layer may be formed above or below the lens layer 105 to prevent irregular or diffused reflection of incident light received from outside, thereby suppressing flare characteristics.

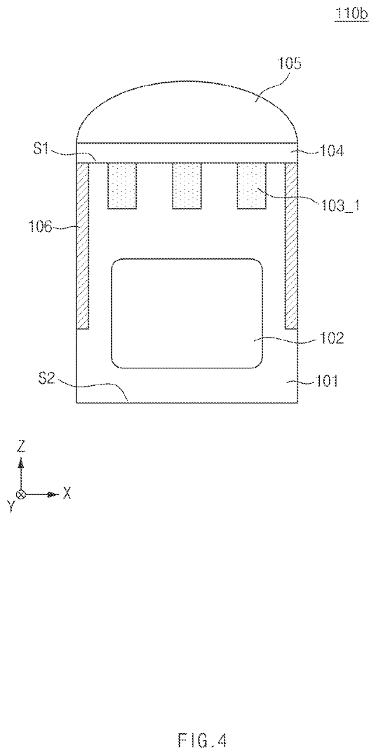

FIGS. 4 to 8 are cross-sectional views illustrating shapes of the polarizer shown in FIG. 2 based on some embodiments of the disclosed technology. A unit pixel 110b contained or disposed in in the pixel array 100 shown in FIGS. 4 to 8 may be substantially identical in structure and function to the unit pixel 110a shown in FIG. 2, and as such redundant description thereof will herein be omitted for brevity. For convenience of description, the unit pixel 110b shown in FIG. 4 will hereinafter be described centering upon the shapes of the polarizers 103.

Referring to FIG. 4, the polarizers 103_1 may be consecutively arranged in the first direction (X-axis direction) at intervals of a predetermined distance. The polarizers 103_1 may be formed below the color filter 104. Thus, the polarizers 103_1 may be formed at a lower portion (i.e., first surface S1) of the color filter 104. The polarizers 103_1 may be disposed between the color filter 104 and the photoelectric conversion element 102. The polarizers 103_1 may be embedded in the substrate 101. Each of the polarizers 103_1 may be formed to have a rectangular-shaped cross-section in the substrate 101. Each of the polarizers 103_1 may be formed in a bar shape in a manner that a vertical length of the third direction (Z-axis direction) of the polarizer 103_1 is longer than a horizontal length of the first direction (X-axis direction) of the polarizer 103_1.

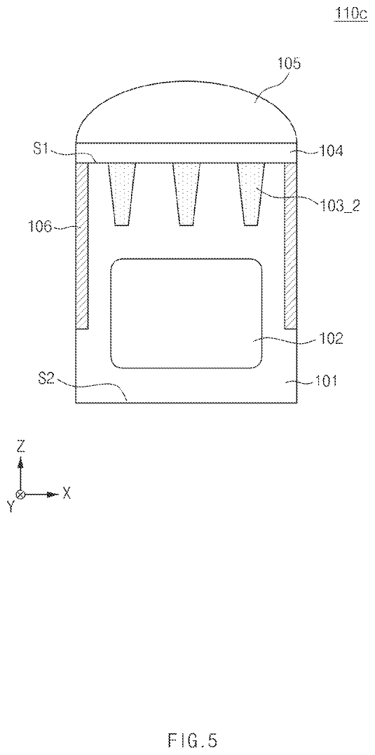

Referring to FIG. 5, the polarizers 103_2 may be consecutively arranged in the first direction (X-axis direction) at intervals of a predetermined distance. The polarizers 103_2 may be formed below the color filter 104. Thus, the polarizers 103_2 may be formed at a lower portion (i.e., first surface S1) of the color filter 104. The polarizers 103_2 may be disposed between the color filter 104 and the photoelectric conversion element 102. The polarizers 103_2 may be embedded in the substrate 101. Each sidewall of the polarizer 103_2 disposed in the substrate 101 may be formed in an inclined shape. As the distance from the first surface S1 increases, the width of a horizontal direction (first direction or X-axis direction) of the polarizer 103_2 may gradually decrease. Thus, each polarizer 103_2 disposed in the substrate 101 may have an inverted trapezoidal cross-section in which the width of a horizontal direction (first direction or X-axis direction) of the polarizer 103_2 gradually decreases in the direction from the first surface S1 to the second surface S2. In the polarizer 103_2 including a top surface and a bottom surface, the top surface contacting the first surface S1 may be longer in length than the bottom surface located close to the second surface S2. As illustrated in the embodiment of FIG. 5, if each polarizer 103_2 is formed in an inverted trapezoidal shape, the width of a polarization direction (e.g., an electrical-field direction) along which light will be transmitted, gradually decreases to increase the amount of light capable of penetrating the polarizer 103, and the polarizer 103_2 can be easily implemented in a fabrication process.

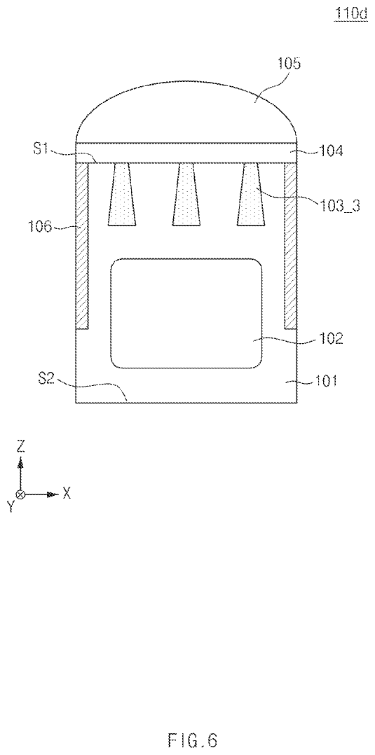

Referring to FIG. 6, the plurality of polarizers 103_3 may be consecutively arranged in the first direction (X-axis direction) at intervals of a predetermined distance. The polarizers 103_3 may be formed below the color filter 104. Thus, the polarizers 103_3 may be formed at a lower portion (i.e., first surface S1) of the color filter 104. The polarizers 103_3 may be disposed between the color filter 104 and the photoelectric conversion element 102. The polarizers 103_3 may be embedded in the substrate 101. Each sidewall of the polarizer 103_3 disposed in the substrate 101 may be formed in an inclined shape. As the distance from the first surface S1 increases, the width of a horizontal direction (first direction or X-axis direction) of the polarizer 103_3 may gradually increase. Thus, each polarizer 103_3 disposed in the substrate 101 may have a trapezoidal cross-section in which the width of a horizontal direction (first direction or X-axis direction) of the polarizer 103_3 gradually increases in the direction from the first surface S1 to the second surface S2. In the polarizer 103_3 including a top surface and a bottom surface, the top surface contacting the first surface S1 may be shorter in length than the bottom surface located closer to the second surface S2.

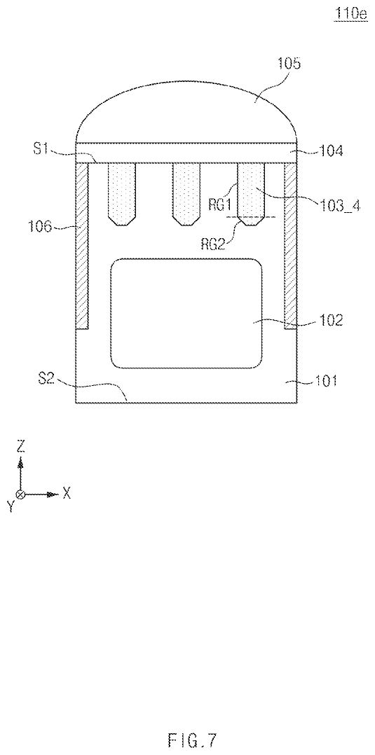

Referring to FIG. 7, the plurality of polarizers 103_4 may be consecutively arranged in the first direction (X-axis direction) at intervals of a predetermined distance. The polarizers 103_4 may be formed below the color filter 104. Thus, the polarizers 103_4 may be formed at a lower portion (i.e., first surface S1) of the color filter 104. The polarizers 103_4 may be disposed between the color filter 104 and the photoelectric conversion element 102. The polarizers 103_4 may be embedded in the substrate 101. In association with each polarizer 103_4 including a first region RG1 and a second region RG2, the first region RG1 adjacent to the first surface S1 may have a rectangular-shaped cross-section, and may be formed in a bar shape in which a vertical length of the third direction (Z-axis direction) of the first region RG1 is longer than a horizontal length of the first direction (X-axis direct) of the first region RG1. In the polarizer 103_4, the second region RG2 adjacent to the second surface S2 may have a trapezoidal cross-section in which the width of a horizontal direction (first direction or X-axis direction) of the polarizer 103_4 gradually decreases in the direction from the first surface S1 to the second surface S2. For example, the polarizer 103_4 may have a cross-section in which the width of a horizontal direction (first direction or X-axis direct) of the polarizer 103_4 remains unchanged within a predetermined range and then gradually decreases in a downward direction. Short-wavelength light may be mostly reflected near the surface (i.e., first surface S1) of the polarizer 103_4 contacting the color filter 104. As a result, metal need not be thickened to a depth located close to the second surface S2, so that the second region RG2 of the polarizer 103_4 can be formed in a trapezoidal shape.

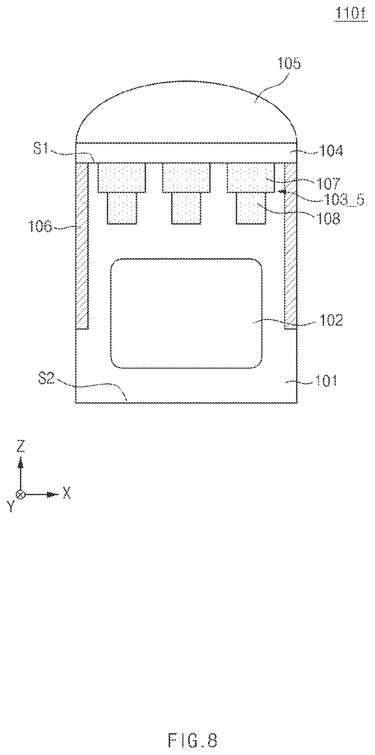

Referring to FIG. 8, the polarizers 103_5 may be consecutively arranged in the first direction (X-axis direction) at intervals of a predetermined distance. The polarizers 103_5 may be formed below the color filter 104. Thus, the polarizers 103_5 may be formed at a lower portion (i.e., first surface S1) of the color filter 104. The polarizers 103_5 may be disposed between the color filter 104 and the photoelectric conversion element 102. The polarizers 103_5 may be embedded in the substrate 101. Each polarizer 103_5 may include a first polarization element 107 formed at an upper side located near the first surface S1, and a second polarization element 108 disposed below the first polarization element 107. The first polarization element 107 may have a rectangular-shaped cross-section, and may be formed in a bar shape in a manner that a vertical length of the third direction (Z-axis direction) of the first polarization element 107 is shorter than a horizontal length of the first direction (X-axis direction) of the first polarization element 107. The second polarization element 108 may be coupled to a bottom surface of the first polarization element 107. The second polarization element 108 may be formed in a square shape in which a vertical length in the third direction (Z-axis direction) of the second polarization element 108 is identical to a horizontal length in the first direction (X-axis direction) of the second polarization element 108. The first polarization element 107 and the second polarization element 108 may be formed to have a T-shaped cross-section. Short-wavelength light may be mostly reflected near the surface (i.e., first surface S1) of the polarizer 103_5 contacting the color filter 104. As a result, metal need not be thickened to a depth located close to the second surface S2, so that the second polarization element 108 may be smaller in width than the first polarization element 107.

FIG. 9 is a perspective view illustrating an example of an embedded structure of wire grid polarizers 103_1. As illustrated in FIG. 9, each of the wire grid polarizers 103_1 may be disposed such that each wire grid polarizer generates polarized light using a conductive wire grid. Each of the polarizers 103_1 embedded in the substrate 101 may be implemented by periodically arranging nanoscopic conductive wires in parallel to each other. The width of the polarizer 103_1 may be denoted by “W”, the height of the polarizer 103_1 may be denoted by “H”, and the length of the polarizer 103_1 may be denoted by “L.

If a spacing between wire grid structures is less than a wavelength of incident light, diffraction may not occur. Accordingly, each wire grid polarizer 103-1 operates to transmit some of the incident light (e.g., transverse magnetic (TM) polarization component) having a vibration direction orthogonal to conductive wire grids, and reflect some other incident light (e.g., transverse electric (TE) polarization component) having a vibration direction parallel to conductive wire grids.

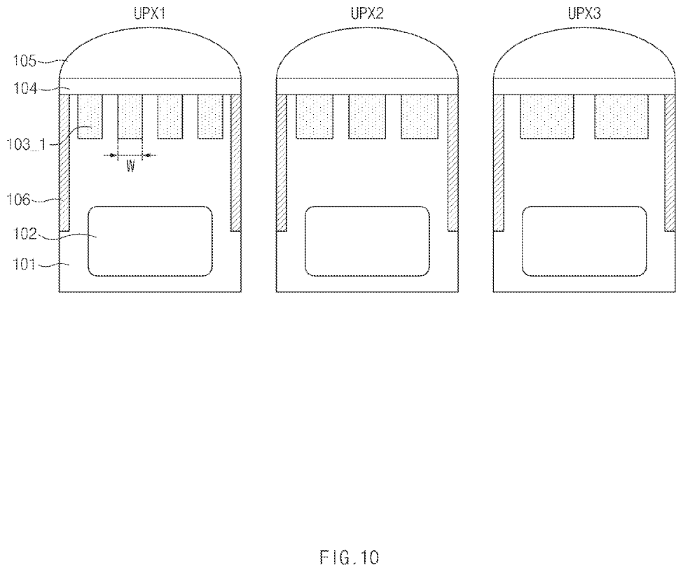

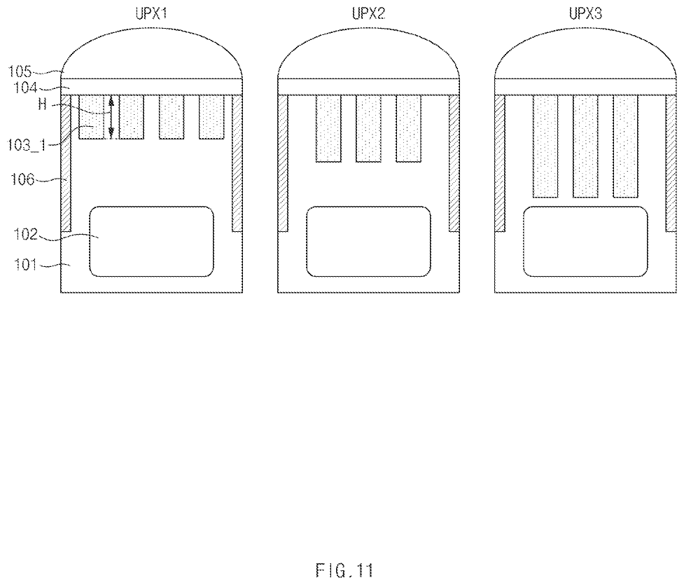

FIGS. 10 and 11 are cross-sectional views of an image sensing device including polarizers based on some implementations of the disclosed technology. Although the polarizers 103_1 have structures as shown in FIG. 4, other structures for the polarizers can be used. For example, the polarizers 103_1 can have structures as shown in FIGS. 2, 5 to 8, or others.

Referring to FIG. 10, the polarizers 103_1 may be formed to have different widths (W) depending on colors of the color filters 104. Thus, the polarizers 103_1 may be formed to have different horizontal widths (W) (i.e., different X-directional widths) depending on colors of the color filters 104.

For example, it is assumed that a color filter 104 of a unit pixel UPX1 is a blue filter BCF, a color filter 104 of a unit pixel UPX2 is a green filter GCF, and a color filter 104 of a unit pixel UPX3 is a red filter RCF. In this case, the blue filter BCF, the green filter GCF, and the red filter RCF are configured to filter the blue, green, and red colored light, respectively. The wavelengths of RGB colored light increases in the order of the blue light, green light, and the red light such that the red light has the longest wavelength and the blue light has the shortest wavelength.

Therefore, the image sensing device based on some embodiments of the disclosed technology can be implemented to increase the width (W) of the polarizer 103_1 in the order of the blue filter BCF, the green filter GCF and the red filter RCF. Thus, the unit pixel UPX1 may be implemented in a manner that each of the polarizers 103_1 corresponding to the blue filter BCF is formed to have the smallest width so that only blue light having the shortest wavelength can penetrate the unit pixel UPX1. The unit pixel UPX3 may be implemented in a manner that each of the polarizers 103_1 corresponding to the red filter RCF is formed to have the largest width so that only red light having the longest wavelength can penetrate the unit pixel UPX3. If each of the polarizers 103_1 corresponding to the red filter RCF having the longest wavelength has the largest width, transmittance of blue light and green light, each of which has a relatively shorter wavelength, can be reduced. In addition, the unit pixel UPX2 may be implemented in a manner that each of the polarizers 103_1 corresponding to the green filter GCF is formed to have an intermediate width so that only green light having a wavelength between blue light and red light can penetrate the unit pixel UPX2. If the polarizer 103_1 corresponding to the green filter GCF having an intermediate wavelength is formed to have an intermediate width, transmittance of blue light having a relatively shorter wavelength can be reduced.

Referring to FIG. 11, the polarizers 103_1 may be formed to have different heights (H) depending on colors of the color filters 104. In other words, the polarizers 103_1 may be formed to have different heights (Z-directional heights) depending on colors of the color filters 104.

As discussed for FIG. 10, it is assumed that the color filter 104 of the unit pixel UPX1 is a blue filter BCF, the color filter 104 of the unit pixel UPX2 is a green filter GCF, and the color filter 104 of the unit pixel UPX3 is a red filter RCF. In this case, the blue filter BCF, the green filter GCF, and the red filter RCF are configured to filter the blue, green, and red colored light, respectively. The wavelengths of RGB colored light increases in the order of the blue light, green light, and the red light such that the red light has the longest wavelength and the blue light has the shortest wavelength.

Therefore, the image sensing device based on some embodiments of the disclosed technology can be implemented to increase the height (H) of the polarizer 103_1 in the order of the blue filter BCF, the green filter GCF, and the red filter RCF. Thus, the unit pixel UPX1 may be implemented in a manner that each of the polarizers 103_1 corresponding to the blue filter BCF is formed to have the smallest height so that only blue light having the shortest wavelength can penetrate the unit pixel UPX1. The unit pixel UPX3 may be implemented in a manner that each of the polarizers 103_1 corresponding to the red filter RCF is formed to have the greatest height so that only red light having the longest wavelength can penetrate the unit pixel UPX3. If each of the polarizers 103_1 corresponding to the red filter RCF having the longest wavelength has the highest height (i.e., the longest length), transmittance of blue light and green light, each of which has a relatively shorter wavelength, can be reduced. In addition, the unit pixel UPX2 may be implemented in a manner that each of the polarizers 103_1 corresponding to the green filter GCF is formed to have an intermediate height that is greater than the height of the the polarizer 103_1 corresponding to the blue filter BCF and smaller than the height of the polarizer 103_1 corresponding to the red filter RCF so that only green light having a wavelength between blue light and red light can penetrate the unit pixel UPX2. That is, if each of the polarizers 103_1 corresponding to the green filter GCF having an intermediate wavelength is formed to have an intermediate height, transmittance of blue light having a relatively shorter wavelength can be reduced.

If each of the polarizers 103_1 is formed to have a sufficient size in a manner that electrons can vibrate in a polarization direction, the polarizers 103_1 can reflect light so that the polarizers 103_1 can prevent the corresponding polarization component from being incident upon the substrate 101. In this case, the above-mentioned sufficient size of the polarizer 103_1 that enables electrons to vibrate in the polarization direction can be determined with respect to wavelengths of RGB lights. As a result, the polarizers 103_1 need not be maintained at the same size in all wavelength bands. Therefore, as a wavelength of target light to be measured increases, the width (W) or height (H) of the polarizer 103_1 increases, so that only desired polarization components can penetrate the polarizer 103_1.

As described above, the image sensing device according to the embodiments of the disclosed technology forms the polarizers 103_1 to have different widths (W) or different heights (H) depending on colors of the color filters 104, thereby reducing transmittance of light having a shorter wavelength than desired color of light to be transmitted. As a result, the image sensing device according to the embodiments of the disclosed technology can reduce crosstalk by minimizing the amount of transmission of the remaining lights other than target light having a target wavelength.

As shown by the disclosure of this patent document, the image sensing device according to embodiments of the disclosed technology can be implemented in ways that effectively prevent or reduce undesired crosstalk while simultaneously minimizing loss of light.

Only a few implementations and examples are described. Variations and enhancements of the implementations and other implementations can be made based on what is described and illustrated in this patent document.

What is claimed is:

1. An image sensing device, comprising:
a substrate including a first surface and a second surface opposite to the first surface;
a color filter disposed over the first surface and configured to transmit light at a certain wavelength to the substrate;
a photoelectric conversion element disposed in the substrate and configured to produce an electric signal in response to the light incident to the photoelectric conversion element; and
one or more polarizers disposed between the first surface and the photoelectric conversion element, and embedded in the substrate, and wherein the one or more polarizers are configured to transmit light of polarization oriented in a specific direction and block light of polarization oriented in other directions than the specific direction.

2. The image sensing device according to claim 1, wherein:
the one or more polarizers are consecutively arranged in a first direction at intervals of a predetermined distance.

3. The image sensing device according to claim 1, wherein:
the one or more polarizers include a wire grid polarizers.

4. The image sensing device according to claim 1, wherein:
the one or more polarizer includes metal.

5. The image sensing device according to claim 1, wherein:
the one or more polarizer have a triangular shaped cross-section, each polarizer having a width that gradually decreases in a direction from the first surface to the second surface.

6. The image sensing device according to claim 1, wherein:
the one or more polarizers have a rectangular shaped cross-section.

7. The image sensing device according to claim 1, wherein:
the one or more polarizers have an inverted trapezoidal shaped cross-section, each polarizer having a width that gradually decreases in a direction from the first surface to the second surface.

8. The image sensing device according to claim 1, wherein:
the one or more polarizers have a trapezoidal shaped cross-section, each polarizer having a width that gradually increases in a direction from the first surface to the second surface.

9. The image sensing device according to claim 1, wherein:
the one or more polarizers have a cross-section such that each of the one or more polarizers has a portion having an unchanged width and another portion having a gradually decreasing width in a downward direction.

10. The image sensing device according to claim 1, wherein the one or more polarizers include:
a first polarization structure formed in a region adjacent to the first surface and having a first width; and
a second polarization structure formed below the first polarization structure and having a second width smaller than the first width.

11. An image sensing device, comprising:
a pixel array including imaging pixels that are arranged in rows and columns, and
wherein each imaging pixel includes:
a substrate;
a photoelectric conversion element disposed in the substrate and configured to produce an electrical signal in response to light incident to the photoelectric conversion element;
a color filter disposed over the substrate and configured to transmit light at a certain wavelength to the photoelectric conversion element; and
a polarizer disposed in the substrate and configured to transmit light of polarization oriented in a specific direction and block light oriented in other directions than the specific direction, and
wherein polarizers of the imaging pixels have different sizes depending on wavelengths of light transmitted by color filters.

12. The image sensing device according to claim 11, wherein the polarizers of the imaging pixels have different widths or different heights.

13. The image sensing device according to claim 11, wherein the imaging pixels include a first imaging pixel, a second imaging pixel, and a third imaging pixel, and
wherein color filters of the first imaging pixel, the second imaging pixel, and the third imaging pixel respectively correspond to a first color filter configured to transmit light of a first color to the first imaging pixel, a second color filter configured to transmit light of a second color to the second imagine pixel, and a third color filter configured to transmit light of a third color to the third imaging pixel.

14. The image sensing device according to claim 13, wherein light of the first to third color correspond to blue, green, and red colored light, respectively.

15. The image sensing device according to claim 14, wherein polarizers of the first to third imaging pixels have widths that increase in an order from the first imaging pixel to the third imaging pixel.

16. The image sensing device according to claim 14, wherein polarizers of the first to third imaging pixels have heights that increase in an order from the first imaging pixel to the third imaging pixel.

17. An image sensing device, comprising:
a substrate including a first surface and a second surface opposite to the first surface;
imaging pixels supported by the substrate and structured to convert light into electrical signals;
a first color filter formed over a first surface and configured to transmit light of a first color towards a first imaging pixel of the imaging pixels;
a second color filter formed over the first surface and configured to transmit light of a second color towards a second imaging pixel of the imaging pixels;
a first polarizer formed below the first color filter and embedded in the substrate to polarize light of the first color that is directed to the first imaging pixel;
a second polarizer formed below the second color filter and embedded in the substrate to polarize light of the second color that is directed to the second imaging pixel.

18. The image sensing device according to claim 17, wherein the first polarizer and the second polarizer have different sizes based on the first color and the second color.

19. The image sensing device according to claim 17, wherein the first polarizer and the second polarizers have side surfaces that are disposed below the first surface.

20. The image sensing device according to claim 17, wherein light of the second color has a longer wavelength than that of light of the first color and wherein a width of the second polarizer is greater than a width of the first polarizer.
